(19) United States
(12) Patent Application Publication
(10) Pub. No.: US 2017/0303367 A1
(43) Pub. Date: Oct. 19, 2017

(54) LED FOR THE EMISSION OF ILLUMINATION RADIATION

(71) Applicant: OSRAM GmbH, Munich (DE)

(72) Inventors: Martin Brueckel, Karlsruhe (DE); Norbert Haas, Langenau (DE); Stephan Schwaiger, Ulm (DE)

(21) Appl. No.: 15/489,770

(22) Filed: Apr. 18, 2017

(30) Foreign Application Priority Data
Apr. 19, 2016 (DE) 10 2016 206 524.6

(51) Int. Cl. H05B 33/08; B60Q 1/04; H01L 33/08; F21S 8/10; H01L 25/075; H01L 33/50; F21Y 2115/10

(52) U.S. Cl. CPC H05B 33/0872; H01L 25/0753; B60Q 1/04; H01L 33/50; H01L 33/08; F21S 48/115; F21S 48/1131; F21Y 2115/10; H01L 2933/0041

(57) ABSTRACT

An LED includes a first active region for the emission of a first primary radiation and a second active region for the emission of a second primary radiation, separate connections, a first phosphor for the at least partial conversion of the first primary radiation into a first conversion radiation in such a way that the first phosphor forms a first emitting surface of the LED for the emission of a first illumination radiation, and a second emitting surface for the emission of a second illumination radiation, which has a different spectral profile than the first illumination radiation, the second illumination radiation originating from the second primary radiation, and the emitting surfaces being shaped and arranged in a plan view, looking at the LED counter to a main emitting direction thereof, such that an outer of the emitting surfaces as a continuous surface area encloses an inner of the emitting surfaces.

### CROSS-REFERENCE TO RELATED APPLICATION

This application claims priority to German Patent Application Serial No. 10 2016 206 524.6, which was filed Apr. 19, 2016, and is incorporated herein by reference in its entirety.

### TECHNICAL FIELD

Various embodiments relate generally to an LED with an emitting surface for the emission of an illumination radiation.

### BACKGROUND

The prior art discloses on the one hand a type of LED (light emitting diode) in which the primary radiation generated in the LED is used directly, that is to say itself forms the illumination radiation of the LED. An example is that of InGaAlP LEDs, in which the illumination radiation/primary radiation is red light. Also disclosed on the other hand is a type of LED in which the LED chip is provided with a wavelength-converting phosphor, which converts the primary radiation at least partly into a conversion radiation. In the case of blue light as primary radiation, a partial conversion into yellow light for example then produces white light as illumination radiation when it is mixed with an unconverted part of the primary radiation. As an alternative to such a partial conversion, also possible however is a full conversion, in which the conversion radiation alone then forms the illumination radiation emitted by the LED.

### SUMMARY

An LED includes a first active region for the emission of a first primary radiation and a second active region for the emission of a second primary radiation, separate connections, a first phosphor for the at least partial conversion of the first primary radiation into a first conversion radiation in such a way that the first phosphor forms a first emitting surface of the LED for the emission of a first illumination radiation, and a second emitting surface for the emission of a second illumination radiation, which has a different spectral profile than the first illumination radiation, the second illumination radiation originating from the second primary radiation, and the emitting surfaces being shaped and arranged in a plan view, looking at the LED counter to a main emitting direction thereof, such that an outer of the emitting surfaces as a continuous surface area encloses an inner of the emitting surfaces.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows an LED according to various embodiments with two emitting surfaces in plan view, an outer of the emitting surfaces enclosing an inner;

FIGS. 2A and 2B show variants of an LED according to various embodiments with two emitting surfaces, in the case of which the inner of the emitting surfaces is segmented;

FIG. 3 shows the structure of an LED according to various embodiments in section;

FIGS. 4A and 4B show various spectral profiles and their influence on the color point.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments provide a particularly advantageous LED.

According to various embodiments, an LED is provided with a first active region for the emission of a first primary radiation and a second active region for the emission of a second primary radiation, the LED having separate connections in such a way that the first active region and the second active region can be operated independently of one another, and the LED also having a first phosphor, which is assigned to the first active region for the at least partial conversion of the first primary radiation into a first conversion radiation in such a way that the first phosphor forms a first emitting surface of the LED for the emission of a first illumination radiation, which originates from the first primary radiation and is at least partly formed by the first conversion radiation, and the LED also having a second emitting surface for the emission of a second illumination radiation, which has a different spectral profile than the first illumination radiation, the second illumination radiation originating from the second primary radiation, and the emitting surfaces being shaped and arranged in a plan view, looking at the LED counter to a main emitting direction thereof, in such a way that an outer of the emitting surfaces as a continuous surface area encloses an inner of the emitting surfaces at least partially, e.g. completely.

Various embodiments can be found in the dependent claims and the disclosure as a whole, a distinction between aspects of the device and method and/or use not always being specifically made in the summary; however, the disclosure should be read implicitly with a view to all of the categories of the claims.

The light emitting diode (LED) according to various embodiments therefore has at least two emitting surfaces. The first emitting surface is supplied with respective primary radiation by way of the first active region and the second emitting surface is supplied with respective primary radiation by way of the second active region. Since the active regions can be operated independently of one another, the emission at the one emitting surface can also be set independently of the emission at the other emitting surface. Therefore, the ratio of the first illumination radiation to the second illumination radiation can be set, and consequently, since the two differ in their spectral profile, the spectral profile of the overall illumination radiation emitted by the LED in total can be set.

In this case, the outer emitting surface may enclose the inner emitting surface completely, or at least partially (see details in this respect below). This arrangement ideally allows a comparatively small overall emitting surface to be realized, so that therefore the emission takes place from a comparatively small surface area. As compared with a comparative case comprising emitting surfaces arranged next to one another, the maximum extent of the overall emitting surface can be reduced, that is to say that for example an overall emitting surface with a smaller difference between the smallest extent and the greatest extent can be realized. The “overall emitting surface” is the entirety of the first emitting surface and the second emitting surface.

In an application, a plurality of LEDs are together installed in an LED module and the latter is assigned an illumination optical system in such a way that the respective overall illumination radiation emitted by a respective LED is guided by way of the illumination optical system into a respective solid angle region. In a front headlamp of a motor vehicle, it is then possible with a corresponding arrangement for example to realize an adaptive illumination of the roadway in which certain solid angle regions are or are not supplied with illumination radiation, depending on whether in the region concerned there is for example a vehicle driving ahead/an oncoming vehicle (a refresh rate may in this case be for example at least 100 Hz and at most 600 Hz).

With the small overall emitting surface of the LED, on the one hand a comparatively narrow or sharply delimited solid angle region can then be supplied with radiation; on the other hand, on account of the adjustable ratio of the first illumination radiation to the second illumination radiation, a certain spectral adaptation is nevertheless possible. In the example mentioned of motor vehicle illumination, the spectral composition for example can be chosen differently for low beam and high beam, for example the latter may have a greater blue component. Furthermore, an adaptive adjustment of the color temperature in dependence on the environment (for example “highway” or “freeway” in comparison with “urban”), the traveling speed (for example bluer overall illumination radiation at a higher traveling speed) and/or driver-related variables, for instance degradation of the eyes caused by age, or fatigue of the eyes after a lengthy journey, is for example also possible. In various embodiments, the coupling between a greater blue light component in the spectrum of the overall illumination radiation and the vehicle speed is of interest, since it is possible as a result to produce an attentiveness effect, e.g. when there are other road users.

“Can be operated independently of one another” primarily concerns suitability of the LED itself; in an LED module it is possible, depending on the wiring or assigned driver/control electronics, for the supply power of the first active region and the second active region to be in a relation to one another that is not constant but nevertheless may have a predefined profile. The LED module or the motor vehicle headlamp (see in detail below) may be designed such that the first active region and the second active region are operated with supply power that is variable in relation to one another, that is to say has in fact for example correspondingly designed driver/control electronics.

That the respective (first or second) illumination radiation “originates” from the respective primary radiation means that what is concerned here is the respective primary radiation itself, the respective conversion radiation (generated in response to the excitation with the respective primary radiation) or a mixture thereof, that is to say partly non-converted respective primary radiation with respective conversion radiation (partial conversion).

Generally, the “primary radiation” may be blue light, that is to say it has for example a wavelength of at least 380 nm; at least 400 nm or at least 405 nm may be provided, it being possible for upper limits to be (irrespective thereof) for example at most 480 nm, 475 nm, or 470 nm (increasingly preferred in the sequence in which they are mentioned). The primary radiation may be monochromatic. The conversion radiation, e.g. the first conversion radiation, may be yellow light, for example with a dominance wavelength of at least 500 nm or at least 530 nm and (irrespective thereof) for example at most 650 nm or 600 nm. At least one illumination radiation may be white light, which for instance in the case of the first illumination radiation may be obtained as a mixture of blue light and yellow light; the same may also be provided for the second illumination radiation. Generally it is also conceivable that for example infrared radiation, which for example may assist a night-vision function or else serve for signal transmission, is emitted as illumination radiation at one of the emitting surfaces.

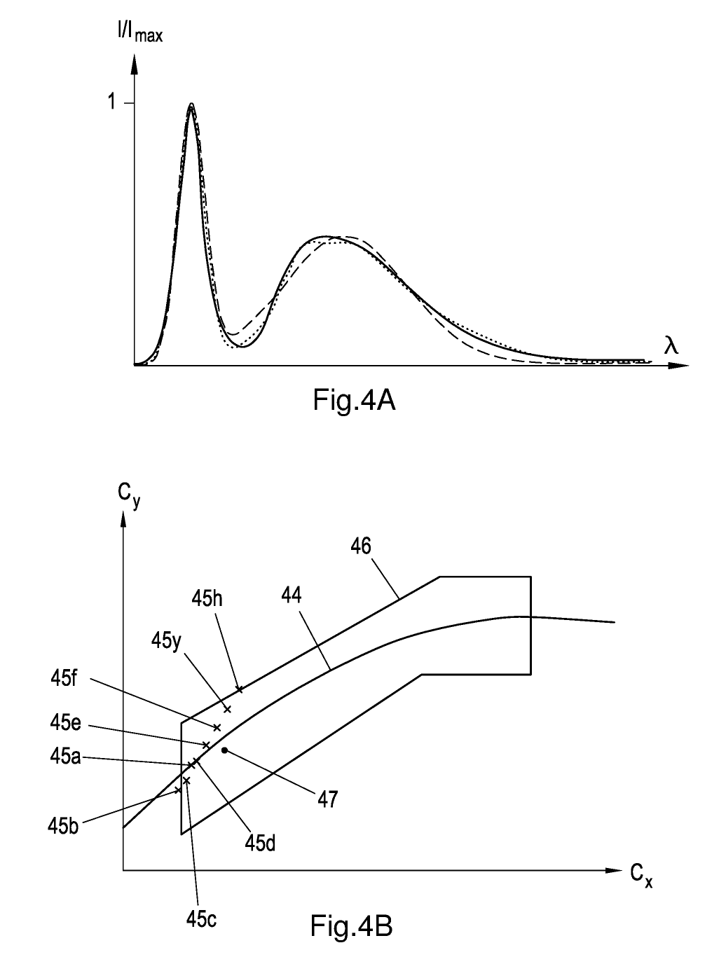

The “different spectral profile” means firstly that, with the same scaling (each normalized to a common maximum value Iₘₐₓ), the corresponding radiation power spectra are not congruent. Plotted over the wavelength in nm on the x axis and with a linear scaling on the x and y axes, in the case of two spectra with a different spectral profile the respective area under a respective spectrum may deviate from a combined area that is obtained as the union of the areas under the spectra by for example at least 1%, 2%, 3%, 4% or 5% (even small deviations can already have a notable influence, see FIGS. 4a, b with description); possible upper limits may be (irrespective thereof) for example at most 20%, 15% or 10% (increasingly preferred in the sequence in which they are mentioned).

In general, in spite of the different spectral profile, the first illumination radiation and the second illumination radiation may nevertheless have the same color, that is to say that for example the color points may coincide in a CIE standard chromaticity diagram (1931 standard colorimetric system); the first illumination radiation and the second illumination radiation may then however differ for example at least in the color reproduction and/or contrast (these considerations concern visible light as the illumination radiation). The first illumination radiation and the second illumination radiation may have different color points on account of the “different spectral profile”.

The “main emitting direction” of the LED is obtained as a mean value of all the directional vectors along which the LED illumination radiation is emitted, in this formation of a mean value each directional vector being weighted with the radiant intensity associated with it. This is based on such uniform operation of the active regions that the surface power densities that are formed in each case for each emitting surface are equal. The main emitting direction may be perpendicular to the emitting surfaces.

The outer emitting surface encloses the inner emitting surface as a “continuous surface area”; in this enclosure there is consequently an uninterrupted path on the outer emitting surface that correspondingly extends at least partially around the inner emitting surface. This would also be the case in general if the outer emitting surface were for example provided with holes, as long as there is an uninterrupted path. The outer emitting surface may be altogether uninterrupted. The resultant overall emitting surface generally may have an area of at least 0.5 mm², e.g. at least 0.8 mm² or 1 mm², it being possible for example for possible upper limits to be (irrespective thereof) at most 12 mm², 10 mm² or 8 mm² (increasingly preferred in the sequence in which they are mentioned).

The consideration “in plan view” is also taken as a basis below when the “partial enclosure” is discussed in further detail. All of these considerations ultimately concern a perpendicular projection of the emitting surfaces into a common plane perpendicular to the main emitting direction; a relative offset of the emitting surfaces in the main emitting direction that may exist, but if so is in any case small in practice, is therefore disregarded. The emitting surfaces preferably lie in fact in a common plane. In general, a movable mounting is also conceivable, in such a way that the emitting surfaces are for example tiltable in relation to one another, for instance by way of a piezo element. A static arrangement may be provided, that is to say that the emitting surfaces are fixed in their relative position in relation to one another.

In the case of various embodiments, the outer emitting surface encloses the inner emitting surface to the extent that straight connecting lines from a centroid of the inner emitting surface to the outer emitting surface fill a continuous angular region of at least 270°. Further lower limits are, increasingly preferred in the sequence in which they are mentioned, at least 280°, 290°, 300°, 310°, 320°, 330°, 340° or 350°; complete enclosure) (360°) may be provided. The “centroid” is obtained as a geometric centroid (the inner emitting surface is considered to be a geometric surface area), that is to say without weighting with the radiant intensity over the surface area. The inner emitting surface may be provided in such a way that its centroid lies in it (in general, it could for example also have a hole in the middle).

In various embodiments, the outer emitting surface encloses the inner emitting surface to the extent that, in its path running around the inner emitting surface it is only interrupted at most in a comparatively small interruption region. This is so because, in the running-around direction, that is to say running around the main emitting direction, it should have a smallest width that makes up at most ⅔, e.g. at most ⅓, e.g. at most ⅙, of a smallest extent of the inner emitting surface. The smallest extent of the inner emitting surface is in this case taken in one of the directions of its surface and corresponds for example in the case of a rectangular form to the extent of its shortest side edge. In graphic terms, even in the case of an outer emitting surface that is not quite closed, but interrupted in a certain region, this interruption region is so small that the inner emitting surface could not (conceptually) be laterally pushed out, that is to say surrounded.

In various embodiments, the inner emitting surface is a continuous surface area, e.g. a quadrangular surface area, with accordingly four side edges. The outer emitting surface then e.g. encloses the inner quadrangular emitting surface to the extent that it outwardly encloses at least three of the side edges, to be precise in each case over the entire length of the respective side edge. In the case of a respective “outwardly enclosed” side edge, all of the straight lines perpendicular to the side edge that extend in each case away from the inner emitting surface in one of its surface directions meet the outer emitting surface. This applies at least to a consideration in plan view or in a common plane after perpendicular projection of the emitting surfaces into this plane (see above); the straight lines then lie in the plane.

Unless otherwise indicated, the indications “inward” and “outward” relate to the surface directions extending away from the centroid of the inner emitting surface that are directed from the inside outward. The “quadrangular” surface area has the form of a convex quadrangle, therefore does not have sides cutting each other/is not concave; the quadrangle may be a rectangle; for example, it may be a square.

In the case of various embodiments, the inner emitting surface is not provided as a continuous surface area but is divided into a plurality of sub-surfaces that are separate from one another. For example, at least 2, e.g. at least 3, e.g. at least 4, sub-surfaces may be provided and (irrespective thereof) for example no more than 10, 8, or 6 sub-surfaces (increasingly preferred in the sequence in which they are mentioned). The inner emitting surface is then therefore segmented, it being possible for the resultant sub-surfaces to be of the same size as one another or else of different sizes. The sub-surfaces may for example be in each case in the form of strips, that is to say in each case have a considerably greater extent in one of the surface directions than in a surface direction perpendicular thereto, for example of at least 2, 3, 4 or 5 times. Possible upper limits may be (irrespective thereof) for example at most 50, 40, 30 or 20 times (increasingly preferred in the sequence in which they are mentioned). Rectangular strips may be provided in each case and the aforementioned indications relate to the longer side edge of the rectangular form in relation to the shorter side edge.

The sub-surfaces are assigned to the same active region, that is to say can be operated jointly. It goes without saying that the outer emitting surface may generally (irrespective of the segmentation of the inner emitting surface) also at least partially enclose (a) further inner emitting surface(s), that is to say that also a number of emitting surfaces that are then in each case supplied by way of an active region of their own and can thus be operated independently of one another could be enclosed. In the case of various embodiments, the outer emitting surface at least partially encloses a plurality of inner emitting surfaces in each case. “Plurality” may to this extent mean for example at least 2 or 3 and (irrespective thereof) for example no more than 20, 15, 10 or 5 inner emitting surfaces. Each of the inner emitting surfaces is supplied in each case with respective primary radiation by an active region of its own, it being possible for these active regions to be operated independently of one another. Where geometric configurations (forms, relative arrangements) of sub-surfaces of a segmented inner emitting surface (that can be operated jointly) are described below, this should also expressly be read as applying to correspondingly geometric configurations of a number of inner emitting surfaces (that can be operated independently of one another).

A number of inner emitting surfaces may then also be operated together in pairs or in groups. Emitting patterns can be set as a variation over time, for instance in the case of an arrangement according to FIG. 2b an emission running around circularly or in the case of FIG. 2a an emission migrating from one side to the other. A correlation with the emission or the emission patterns of other LEDs of an LED module is also possible, so that for example in the case of a number of LEDs according to FIG. 2a the emission (of the emitting strips) may migrate not only within a respective LED, but also from LED to LED.

In a simple case, however, it may nevertheless be provided that the LED has precisely two active regions, and accordingly two emitting surfaces and consequently precisely one inner emitting surface.

In the case of a segmentation of the inner emitting surface into strips (or a number of inner, strip-shaped emitting surfaces), these may be of the same length and arranged parallel to one another. However, it is also possible for them to differ in length, also in combination with an arrangement parallel to one another, so that for example the strip length increases outwardly, that is to say that there is a middle strip of the shortest length that is enclosed on both sides by strips of increasingly greater length. The strips also do not necessarily have to be arranged in parallel, at least not all of them, but may for example also lie on the side edges of an (imaginary) rectangle. Furthermore, other geometric forms are also possible, for example also triangular and/or round sub-surfaces (or inner emitting surfaces), also in combination with for example a strip-shaped sub-surface (inner emitting surface). The sub-surfaces (inner emitting surfaces) may for example be arranged in such a way that their area increases from the inside outward. On the other hand, however, a randomly distributed arrangement is also possible, e.g. in the case of very large LEDs with many sub-surfaces (inner emitting surfaces).

In the case of various embodiments, the emission at the second emitting surface is conversion-free, that is to say that the second primary radiation exclusively forms the second illumination radiation. The second primary radiation may be blue light (see above), that is to say that the blue component mixed in with the overall illumination radiation can be set. The “overall illumination radiation” is generally the illumination radiation emitted by the LED altogether at its emitting surfaces. The overall illumination radiation may be for example white light, the color point of which can be set, at least within certain limits, by way of the blue component mixed in by means of the second emitting surface.

In a configuration, the first emitting surface, which is formed by the first phosphor, is the outer emitting surface. Accordingly, the second emitting surface is then the inner, enclosed emitting surface. At the inner emitting surface, the emission may be conversion-free (see above).

In the case of various embodiments which concerns the second emitting surface with conversion-free emission, it has an area that is in a ratio to the area of the first emitting surface of at most 2:3. If exclusively the first conversion radiation is emitted at the first emitting surface, that is to say no primary radiation (full conversion), lower limits may be for example at least 1:19, 1:9 or 1:4 (area ratio of the second emitting surface to the first emitting surface), increasingly preferred in the sequence in which they are mentioned. In the case of a partial conversion in the first phosphor, the first illumination radiation already has some primary radiation, and accordingly the second emitting surface can be somewhat smaller, that is to say that lower limits can be for example at least 1:99, 1:19, 1:9 or 3:17 (increasingly preferred in the sequence in which they are mentioned); correspondingly, in the partial conversion a lower-lying upper limit may be provided, for example at most 3:7 or 1:4 (the upper limit and the lower limit may also be of interest independently of one another).

These limits may be chosen such that, over as great an operating range as possible (varying combination of the supplied power in the active regions), the resultant overall illumination radiation ideally has a color point in the ECE white zone (see below). The area ratio indications preferably concern blue light as the primary radiation in combination with a yellow converter (yellow conversion radiation), e.g. YAG:Ce.

In the case of various embodiments that is different from the “conversion-free second emitting surface”, the LED has a second phosphor, which is assigned to the second active region for the at least partial conversion of the second primary radiation into a second conversion radiation. The second conversion radiation forms partly (partial conversion) or completely (full conversion) the second illumination radiation. The second conversion radiation may have a different spectral profile than the first conversion radiation (cf. the definition thereof at the beginning).

In general, the spectral profile could however also be the same, and the first phosphor and the second phosphor could for example just have a different thickness. Taken along the main emitting direction, the thickness of the phosphor may generally be for example at least 10 μm and (irrespective thereof) for example no more than 200 μm or 100 μm (in the case of a thickness that is not uniform over the respective emitting surface, a mean value formed by way thereof is considered).

“Phosphor” should be read as applying generally also to a mixture of a number of individual phosphors. The first phosphor and the second phosphor may differ, that is to say that for example at least one of the two has an individual phosphor that the other phosphor does not have. The phosphors may however also for example differ to the extent that, although they have the same individual phosphors, the relative proportions thereof in the mixture for the first phosphor and the second phosphor are different. Furthermore, it is even also conceivable that the phosphors have the same individual phosphors in the same concentration, but a difference between the first phosphor and the second phosphor arises for example from differences in the concentration and/or type of embedded scattering centers. It goes without saying that a combination of the possibilities just described is also conceivable.

Different influencing of the conversion radiation that is ultimately emitted at the respective emitting surface is not only possible by way of the “internal” influencing variables just described; “external” means can also bring about a difference, for example different filters and/or dichroic mirrors between the respective phosphor and the respective active region.

Also conceivable in general would be an LED with active regions that can be operated independently of one another, the respective primary radiation of which is spectrally identical and to which in each case a phosphor with spectrally identical respective conversion radiation is also assigned. Furthermore, a filter could then be arranged in each case on both phosphors, these filters differing and the different spectral profiles only being established in this way.

Apart from the already discussed yellow light, the first conversion radiation and/or the second conversion radiation may also be for example red light (for example peak wavelength of 600 nm to 650 nm) and/or green light (for example 500 nm to 560 nm). With respect to possible phosphors, reference is made by way of example to DE 10 2004 038 199 A1, U.S. Pat. No. 7,825,574 B2, U.S. Pat. No. 8,928,019 B2 and DE 10 2013 215 382 A1. Also possible as a variant is for example amber, that is to say a kind of orange light, which may be of interest for example for a direction indicator (flasher); with respect to a corresponding phosphor, reference is made by way of example to WO 2015/052238 A1. A yellow/orange phosphor may be provided; the conversion radiation emitted therefrom is also referred to as converted yellow. The conversion radiation and/or the illumination radiation may then lie in the CIE standard chromaticity diagram for example in the region of selective yellow. An individual phosphor may be for example cerium-doped yttrium aluminum garnet (YAG:Ce). The conversion may generally be a down conversion, that is to say that the conversion radiation is of a longer wavelength than the primary radiation.

In a configuration, the first primary radiation and the second primary radiation have the same spectral profile; the normalized radiation power spectra are therefore congruent (see in detail above).

In a configuration, the LED can be operated in such a way that the first illumination radiation and the second illumination radiation when mixed give white light. “White light” means light of which the color point in a CIE standard chromaticity diagram (1931) is in the ECE white zone according to ECE/324/Rev.1/Add.47/Reg.No.48/Rev.12. It may also be provided that the first illumination radiation and the second illumination radiation are in each case already themselves white light; the first illumination radiation and the second illumination radiation may then for example differ in the color temperature; white light of a higher color temperature may be emitted at the inner emitting surface than at the outer emitting surface (for example 5600 K in comparison with 5400 K).

An LED module or an illumination unit, in particular a motor vehicle headlamp, with the LED according to various embodiments may be designed for operation in such a way that in every operating state the color point of the overall illumination radiation lies in the ECE white zone. The latter should therefore not be left even if the supply power of the one active region is at a minimum and that of the other active region is at a maximum, and vice versa.

Generally, the active regions may be operated in a pulsed manner, the average supply power more e.g. being set in a pulse width modulated (PWM) manner. In this case, the frequencies of the pulsed operation of the first active region and the second active region may for example also differ and/or a frequency may be additionally modulated onto the pulsed operation. With a frequency coding, or in general terms “electrical modulation”, a signal transmission for example can be realized, for instance to other road users “car to car” or to the environment “car to environment”. If in the case of pulsed operation, the current amplitude is varied, it is consequently also possible that the color point of the respective illumination radiation itself may be changed a little (color point shift due to so-called “DC PWM” adaptation). The illumination radiation itself does not have to be affected by this, at least not if the limits of human perception, e.g. over time, are taken into consideration. The signal detection of a sensor that is for example tuned to the wavelength of the respective primary radiation, for instance is provided with a corresponding filter layer, can however ideally be improved.

In the case of various embodiments, the first active region and the second active region are at a smallest distance from one another of at most 500 μm, e.g. in this sequence at most 400 μm, 300 μm, 200 μm, 100 μm, 50 μm, 30 μm or 20 μm; possible lower limits (irrespective thereof) may be for example at least 5 μm or 10 μm.

In general, the emitting surfaces may also be flush, that is to say directly adjoin one another. On the other hand, however, they may also be separated by way of an intermediate region that does not light up itself, for instance a separating wall or a region that is filled, for instance with a filler material such as silicone or casting resin. An intermediate region may for example serve for mechanical stiffening and/or heat transfer. The intermediate region may also be optically opaque, for instance in the case of nano-hybrid composites.

In the case of various embodiments, the active regions are arranged in different regions of the same LED chip, that is to say that they are produced for example in a common front-end process. The regions of the LED chip share at least a semiconductor layer that is continuous with respect to directions perpendicular to the main emitting direction; others of the semiconductor layers may be interrupted between the regions, for example by way of a trench, which may also be filled with an insulator, for instance an oxide. “Semiconductor” should be read as applying both to compound semiconductors, such as for example GaAs or GaN, and to semimetals, such as for example Ge or Si. In the case of the LED chip, an own anode contact and an own cathode contact may then be provided in each case for the first active region and the second active region.

In general, however, “LED” should not necessarily be read as applying to a single LED chip, but instead the LED may also be made up of a number of LED chips. Generally, the LED chip(s) of the LED may for example be mounted in a “flipchip” arrangement, the anode contact and the cathode contact of the LED chip(s) facing downward toward a mounting body, counter to the main emitting direction. Such a mounting body, which is part of the LED, may be provided as a printed circuit board and is also referred to as a submount. Furthermore, the mounting of the LED chip may also be embodied as a so-called planar interconnect, a (planar) interconnect structure being provided on an upper side (with respect to the main emitting direction) of the LED chip and connected to a mounting body (submount) for example by way of vertical interconnect accesses (vias).

In both ways, bond-free contacting can be realized, so that the emission is not impaired by wire bonds. In general, however, contacting by way of wire bonds is also conceivable. Between the inner emitting surface and the outer emitting surface there may be provided in this case a clearance which extends (counter to the main emitting direction) up to the mounting body and through which wire bonds can extend from the upper side of the LED chip(s) to the mounting body. An interconnect structure provided on the upper side of the LED chip(s) (with respect to the main emitting direction) may generally be of a translucent/transparent configuration, for instance of indium tin oxide (ITO).

Various embodiments also relate to an LED module with an LED disclosed in the present case, which is mounted with further LEDs on a common substrate, for instance a printed circuit board. With respect to the meaning of “LED”, generally reference is expressly made also to the statements made in the introductory part of the description. However, the “LED” does not necessarily have to be provided with (an) inorganic LED chip(s), but may in general also be constructed on the basis of an organic LED (OLED). In the module, at least one LED with emitting surfaces nested according to various embodiments is then provided, preferably a plurality of such LEDs, e.g. all of the LEDs. Irrespective thereof, specifically the LEDs of the module may for example be arranged next to one another in the form of a row; a matrix-shaped arrangement with in each case a plurality of rows and columns may be provided.

Various embodiments also relate to a method for producing an LED, the first active region and the second active region already being fixed in their relative position in relation to one another when the first phosphor is applied. In general, the first phosphor may for example also be applied in a prefabricated form, for instance as phosphor platelets. If the first phosphor forms the outer emitting surface, a central region may be removed from the phosphor platelet, exposing the second emitting surface, this taking place before the application. The central region may for example be punched out. The phosphor platelet is preferably connected to the LED chip by way of a joining connection, e.g. adhesively attached. The central region may remain free, or a further phosphor platelet may be inserted.

On the other hand, application of the phosphor as a coating may also be provided, for instance involving electrophoretic deposition or a spraying process. The region of the LED that is generally not to be provided with phosphor, or at least not with the phosphor of the other region, may either be subsequently exposed again, for instance by laser ablation, or preferably masked (covered) in advance, for instance with photoresist.

Various embodiments consequently also relate to the use of an LED or an LED module disclosed in the present case, for illumination, in particular for illumination on or in a motor vehicle, e.g. an automobile. In this case, use in the interior for example is also conceivable, but use in the area of the exterior illumination may be provided. In the case of the brake lights, an advantageous use may arise for example to the extent that a changed color shade of the brake light indicates particularly strong deceleration of the vehicle, for example by darker red. In a flasher lamp, a changed color point may for example make the normal flashing operation for directional indication distinguishable from hazard warning operation. These are examples of illumination “in dependence on a state of the vehicle”. Ideally, both a flashing light function (amber) and a daytime running light function (white) can be realized with a respective LED, so that these two functionalities can then also be correspondingly changed over with the same illuminating optical system. For example, brief lighting up at one of the illuminating surfaces can signal a deactivation of the vehicle locking system or immobilizer independently of the normal function of the lamp. Further application examples have already been described further above.

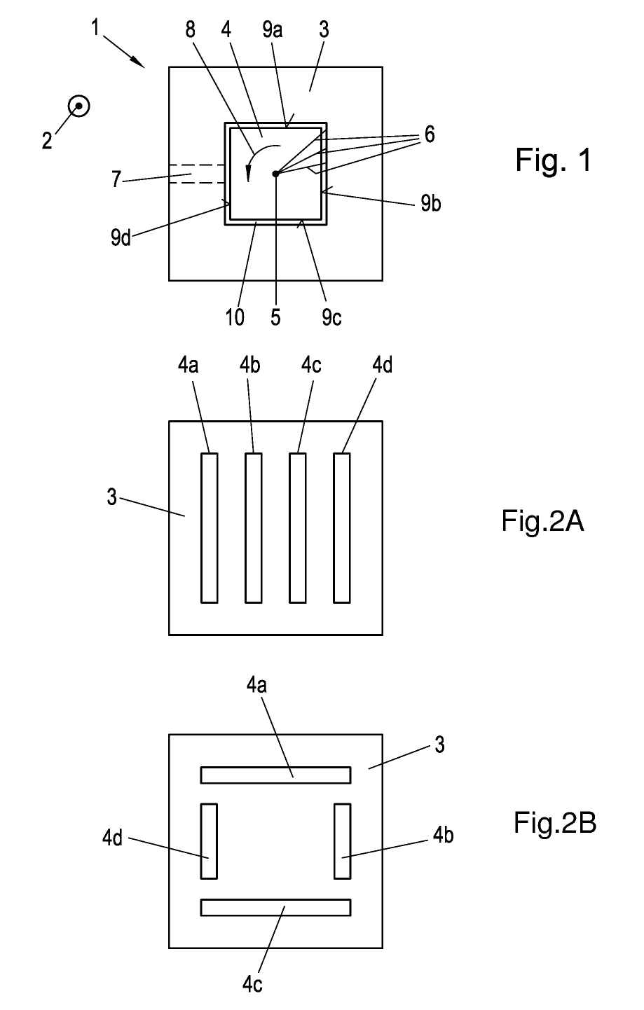

FIG. 1 shows an LED 1 according to various embodiments, to be precise counter to a main emitting direction 2, which is perpendicular to the plane of the drawing, looking onto it. The LED 1 has a first emitting surface 3 and a second emitting surface 4, the first emitting surface 3 as an outer surface enclosing the second emitting surface 4 as an inner surface.

In the present case, the first emitting surface 3 encloses the second emitting surface completely, that is to say that straight connecting lines 6 (only some are shown by way of example) extending from a centroid 5 of the second emitting surface 4 to the first emitting surface 3 fill an angle of 360°. The first emitting surface 3 could however in general also be interrupted in an interruption region 7 (indicated by dashed lines). Such an interruption region 7 would then have a smallest width, taken in the running-around direction 8, of at most ⅙ of the smallest extent of the second emitting surface 4, that is to say at most ⅙ of the edge length of the square. In the present case, without the interruption region 7, the first emitting surface 3 outwardly encloses all of the side edges 9a, b, c and d of the second emitting surface 4; if it were interrupted in the interruption region 7, it would still outwardly enclose the three side edges 9a, b and c, in each case completely over their entire length.

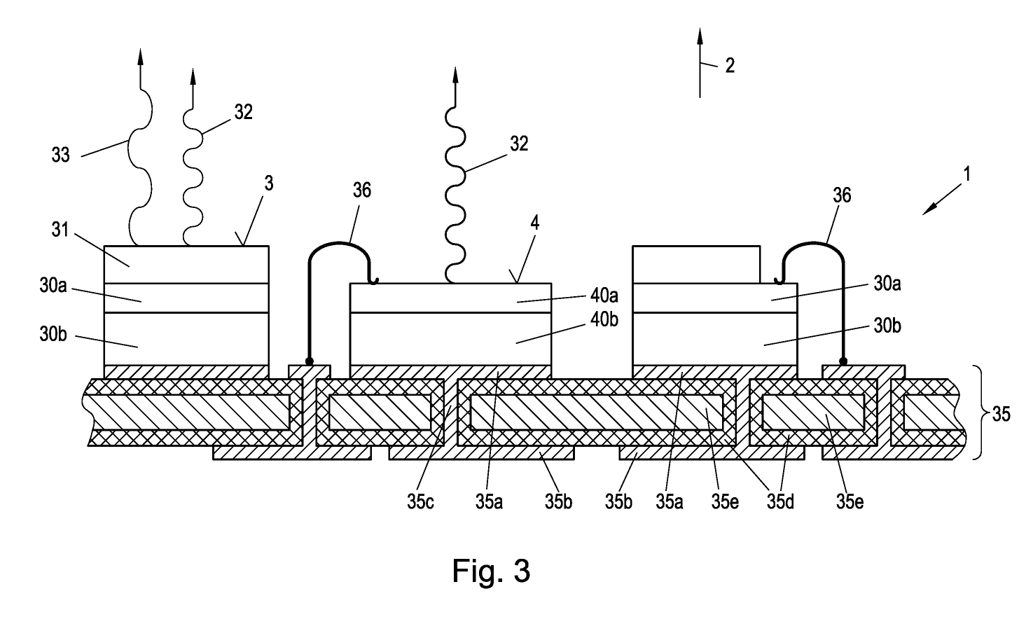

In the example according to FIG. 1, a separating region 10 that does not light up is arranged between the emitting surfaces 3, 4, which may correspond to a structure according to FIG. 3 (see below). The emitting surfaces 3, 4 could however also adjoin one another directly, for instance in the case of flipchip mounting or in the case of emitting surfaces 3, 4 that are formed on the same LED chip.

A first illumination radiation is emitted at the first emitting surface 3 and a second illumination radiation, which has a different spectral profile than that of the first (see in detail below), is emitted at the second emitting surface 4. The ratio of the first illumination radiation to the second illumination radiation can be set, whereby the spectral profile of the resultant overall illumination radiation can also be set on account of the different spectral profile.

With respect to advantageous application areas, reference is made expressly to the introductory part of the description. On account of the arrangement of the emitting surfaces 3, 4 nested in one another, the overall illumination radiation is nevertheless emitted from a comparatively small surface region and can be fed by way of an illumination optical system to a correspondingly narrow, sharply delimited solid angle region, to be precise in spite of the spectral adjustability.

FIG. 2a, FIG. b then show variants of an LED 1 according to various embodiments, in which the second emitting surface 4 is divided into sub-surfaces 4a-d. However, in the present case the sub-surfaces 4a-d are supplied by a common active region (see in detail below), that is to say that the emission can only be changed jointly for the sub-surfaces 4a-d. Such a segmentation of the second emitting surface 4 may for example offer various effects with regard to the mixing of the first illumination radiation and the second illumination radiation.

Otherwise also possible however are a number of inner emitting surfaces (not specifically shown, arranged by analogy with the sub-surfaces), which can be operated independently of one another (also see the introductory part of the description). The emission at these inner emitting surfaces could then correspond in the variation over time to prescribed patterns or be stochastic; for example, each of the inner emitting surfaces could be operated in an independently clocked manner (for example flash mode). If the number of LEDs are combined in a module, the LEDs (the emission at their respective emitting surfaces) may be tuned to one another, for instance for the achievement of dynamic effects, or else be completely synchronized; emitting surfaces corresponding to one another of the various LEDs are operated in the same way, for instance also in phase.

In the case of the variant according to FIG. 2a, the sub-surfaces 4a-d—which in the example shown can be activated jointly—are strips of the same length arranged parallel to one another. As an alternative to this, for example strips which, though arranged parallel to one another, differ at least partially in their length would also be conceivable; for example, a shortest central strip could be outwardly enclosed by strips of increasing length (it being possible for the outer strips in pairs, on opposite sides of the central strip, also to have the same length).

In the case of the variant according to FIG. 2b, the second emitting surface 4 is likewise divided into four sub-surfaces 4a-d, the strips not being arranged (completely) parallel to one another, but on the side edges of an imaginary quadrangle. It goes without saying that further geometric forms or arrangements are also conceivable for the sub-surfaces 4a-d; for example, a triangular sub-surface could therefore be combined with a strip-shaped sub-surface, etc. Furthermore, it goes without saying that, even in the case of a non-segmented second emitting surface 4, the latter does not necessarily have to have the form according to FIG. 1, but could for example also be round, e.g. circular.

FIG. 3 shows an LED 1 analogous to that according to FIG. 1 in a schematic section in a sectional plane parallel to the main emitting direction 2 (through the centroid 5). In this case, the LED 1 is constructed from a first LED chip 30 and a second LED chip 40. Both LED chips 30, 40 are in each case an InGaN chip, the layer structure of which is not specifically represented in each case, but instead is in each case only schematically divided into an active region 30a, 40a and a remaining semiconductor layer system 30b, 40b.

In the respective active region 30a, 40a, blue light is generated in each case as primary radiation 32. Arranged on the first LED chip 30 is a first phosphor 31, which converts this primary radiation 32 partly into a longer-wavelength first conversion radiation 33. The first phosphor 31 is YAG:Ce, and the first conversion radiation 33 is accordingly yellow light. As the first illumination radiation, a mixture of partly non-converted primary radiation 32 and conversion radiation 33 is then emitted. The first phosphor 31 forms the first emitting surface 3.

The second LED chip 40 is not assigned any phosphor; the LED chip itself forms the second emitting surface 4. At this, the primary radiation 32 is accordingly emitted conversion-free. Since the second LED chip 40, and consequently the second active region 40a, can be operated independently of the first LED chip 30, the blue component of the overall illumination radiation can be set. The operating modes may then be different (pulsed/continuous), in antiphase, or else synchronous. This offers great variability, as far as the spectral mixing ratios and possible ‘stroboscope” effects are concerned.

The LED chips 30, 40 are arranged on a common mounting body 35, to be specific in the present case a metal-core PCB. This is provided on the upper side and underside (with respect to the main emitting direction 2) in each case with an interconnect structure 35a, b, the upper-side interconnect structure 35a being connected to the underside interconnect structure 35b by way of vertical interconnect accesses 35 (vias). The vertical interconnect accesses 35c pass through a dielectric 35d, in which the metal core 35e is embedded for thermal optimization. The dielectric 35d insulates the metal core 35e from the vertical interconnect accesses 35c and the interconnect structures 35a, b.

The LED chips 30, 40 are connected in an electrically conducting manner in each case by way of a back-side contact to the upper-side interconnect structure 35a (in each case a part thereof). Furthermore, a front-side contact (not represented) of the respective LED chip 30, 40 is also in each case connected to the upper-side interconnect structure 35a in each case by way of a bonding wire 36. With the back-side connection and the front-side connection, anode contact and cathode contact are therefore then respectively realized, it being possible for these contacts to be tapped on the underside of the mounting body 35 at the interconnect structure 35b.

As an alternative to the configuration with two LED chips 30, 40, an LED according to various embodiments could also be realized with a single LED chip, for instance by taking an LED chip with continuous semiconductor layers and interrupting some of these semiconductor layers (for example by trench etching), and the active regions that can be activated separately from one another being realized in this way.

FIG. 4a, FIG. b illustrate the influence of the spectral profile on the color point. This is so because even comparatively small deviations in the spectral profile can already cause a notable difference in the color point. In FIG. 4a, three slightly different spectra are shown, the normalized radiation power (I/Iₘₐₓ) being plotted in each case over the wavelength λ. The solid line corresponds to the spectrum of a reference LED with a phosphor in partial conversion; a pronounced peak in the blue (blue component) and the comparatively wider yellow component, which the conversion radiation forms, can be seen.

The two further spectra show variations (achieved by adaptations, fits) of the first-mentioned spectrum, to be precise a first variation (dashed line) and a second variation (dotted line).

FIG. 4b then shows an extract from a CIE standard chromaticity diagram. Depicted in it firstly is the Planck curve 44, for orientation. Also depicted are various color points 45, the color point 45a corresponding to the reference spectrum according to FIG. 4a (solid line there), the color point 45b corresponding to the adaptation “first variation” and the color point 45c corresponding to the adaptation “second variation”.

The blue component in the reference spectrum is at 32%; nevertheless, the resultant color point 45a is “warmer” than the color points 45b, c, in the spectra of which the blue component was in each case only around 30%. The color point 45a has a correlated color temperature of around 6350 K, the color point 45c around 6550 K and the color point 45b around 6850 K. This illustrates that even relatively small deviations in the spectral profile (cf. FIG. 4a) can have as a consequence notable differences in the color point.

Also depicted in FIG. 4b are further color points 45d-h, in the case of which, on the basis of the “first variation” spectrum, the blue component has been reduced, to be precise to 27% (45d), 26% (45e), 24% (45f), 22% (45g) and 20% (45h). This illustrates how the color point 45 can be changed by a variation of the blue component, which can in fact be realized by a variation of the supplied power of the second LED chip 40 (FIG. 3).

In FIG. 4b there can also be seen a polyline 46, which reproduces the ECE white zone. Operation of the LED in such a way that, irrespective of the relative ratio of the first illumination radiation and the second illumination radiation, the color point of the overall illumination radiation always lies in the ECE white zone 46 may be provided. For orientation, finally the white point 47 is also depicted.

### LIST OF REFERENCE SIGNS

LED 1
main emitting direction 2
first emitting surface 3
second emitting surface 4
sub-surfaces thereof 4a-d
centroid 5
straight connecting line 6
interruption region 7
running-around direction 8
side edges (of the first emitting surface) 9a-d
separating region 10
first LED chip 30
active region thereof 30a
and remaining semiconductor layer system 30b
phosphor 31
primary radiation 32
first conversion radiation 33
mounting body 35
interconnect structure 35a, b
on the upper side thereof 35a
and on the underside 35b
vertical interconnect accesses 35c
dielectric 35d
metal core 35e
bonding wire 36
second LED chip 40
active region thereof 40a
and remaining semiconductor layer system 40b
Planck curve 44
color points 45a-h
ECE white zone 46
white point 47

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A light emitting diode, comprising:
a first active region for the emission of a first primary radiation and
a second active region for the emission of a second primary radiation,
the light emitting diode having separate connections in such a way that the first active region and the second active region can be operated independently of one another,
and the light emitting diode also having a first phosphor, which is assigned to the first active region for the at least partial conversion of the first primary radiation into a first conversion radiation in such a way that the first phosphor forms a first emitting surface of the light emitting diode for the emission of a first illumination radiation, which originates from the first primary radiation and is at least partly formed by the first conversion radiation,
and the light emitting diode also having a second emitting surface for the emission of a second illumination radiation, which has a different spectral profile than the first illumination radiation, the second illumination radiation originating from the second primary radiation,
and the emitting surfaces being shaped and arranged in a plan view, looking at the light emitting diode counter to a main emitting direction thereof, in such a way that an outer of the emitting surfaces as a continuous surface area encloses an inner of the emitting surfaces at least partially.

2. The light emitting diode of claim 1,
wherein the outer emitting surface encloses the inner emitting surface to the extent that straight connecting lines from a centroid of the inner emitting surface to the outer emitting surface fill a continuous angular region of at least 270°.

3. The light emitting diode of claim 1,
wherein the outer emitting surface encloses the inner emitting surface to the extent that it extends in a path running around the inner emitting surface and in this path is interrupted at most in an interruption region which has a smallest width, taken in the running-around direction, that makes up at most ⅔ of a smallest extent of the inner emitting surface.

4. The light emitting diode of claim 1,
wherein the inner emitting surface is a continuous quadrangular surface area, and accordingly has four side edges, the outer emitting surface enclosing the inner emitting surface to the extent that it outwardly encloses at least three of the side edges, to be precise in each case over an entire length of the respective side edge.

5. The light emitting diode of claim 1,
wherein the inner emitting surface is divided into a plurality of sub-surfaces that are separate from one another.

6. The light emitting diode of claim 1,
wherein the inner emitting surface is one of a plurality of inner emitting surfaces, which are in each case enclosed at least partially by the outer emitting surface, each of the inner emitting surfaces being assigned a respective active region and it being possible for these active regions to be operated independently of one another

7. The light emitting diode of claim 1,
wherein the emission at the second emitting surface is conversion-free, that is to say that the second illumination radiation is formed exclusively by the second primary radiation.

8. The light emitting diode of claim 7,
wherein the first emitting surface, which is formed by the first phosphor, is the outer emitting surface and the second emitting surface, at which the emission is conversion-free, is the inner emitting surface.

9. The light emitting diode of claim 7,
wherein the second emitting surface has an area that is in a ratio to the area of the first emitting surface of at most 2:3.

10. The light emitting diode of claim 1, further comprising:
a second phosphor, which is assigned to the second active region for the at least partial conversion of the second primary radiation into a second conversion radiation, which forms at least partly the second illumination radiation, the second phosphor forming the second emitting surface of the light emitting diode for the emission of the second illumination radiation.

11. The light emitting diode of claim 1,
wherein the first primary radiation and the second primary radiation have the same spectral profile.

12. The light emitting diode of claim 1,
configured in such a way that the first illumination radiation and the second illumination radiation when mixed form white illumination light.

13. The light emitting diode of claim 1,
wherein the first active region and the second active region are at a smallest distance from one another of at most 500 μm.

14. The light emitting diode of claim 1,
wherein the first active region and the second active region are arranged in different regions of the same light emitting diode chip, which regions share at least a semiconductor layer that is continuous with respect to directions perpendicular to the main emitting direction.

15. A light emitting diode module, comprising:
a common substrate; and
a plurality of light emitting diodes, each light emitting diode comprising:
a first active region for the emission of a first primary radiation and
a second active region for the emission of a second primary radiation,
the light emitting diode having separate connections in such a way that the first active region and the second active region can be operated independently of one another,
and the light emitting diode also having a first phosphor, which is assigned to the first active region for the at least partial conversion of the first primary radiation into a first conversion radiation in such a way that the first phosphor forms a first emitting surface of the light emitting diode for the emission of a first illumination radiation, which originates from the first primary radiation and is at least partly formed by the first conversion radiation,
and the light emitting diode also having a second emitting surface for the emission of a second illumination radiation, which has a different spectral profile than the first illumination radiation, the second illumination radiation originating from the second primary radiation,
and the emitting surfaces being shaped and arranged in a plan view, looking at the light emitting diode counter to a main emitting direction thereof, in such a way that an outer of the emitting surfaces as a continuous surface area encloses an inner of the emitting surfaces at least partially,
wherein the plurality of light emitting diodes is mounted together on the common substrate.

16. A method for producing a light emitting diode,
the light emitting diode comprising:
a first active region for the emission of a first primary radiation and
a second active region for the emission of a second primary radiation,
the light emitting diode having separate connections in such a way that the first active region and the second active region can be operated independently of one another,
and the light emitting diode also having a first phosphor, which is assigned to the first active region for the at least partial conversion of the first primary radiation into a first conversion radiation in such a way that the first phosphor forms a first emitting surface of the light emitting diode for the emission of a first illumination radiation, which originates from the first primary radiation and is at least partly formed by the first conversion radiation,
and the light emitting diode also having a second emitting surface for the emission of a second illumination radiation, which has a different spectral profile than the first illumination radiation, the second illumination radiation originating from the second primary radiation,
and the emitting surfaces being shaped and arranged in a plan view, looking at the light emitting diode counter to a main emitting direction thereof, in such a way that an outer of the emitting surfaces as a continuous surface area encloses an inner of the emitting surfaces at least partially,
the method comprising:
producing the first active region and the second active region; and
fixing the first active region and the second active region already in their relative position in relation to one another when the first phosphor is provided.

17. A motor vehicle, comprising:
a light emitting diode module, comprising:
a common substrate; and
a plurality of light emitting diodes, each light emitting diode comprising:
a first active region for the emission of a first primary radiation and
a second active region for the emission of a second primary radiation,
the light emitting diode having separate connections in such a way that the first active region and the second active region can be operated independently of one another,
and the light emitting diode also having a first phosphor, which is assigned to the first active region for the at least partial conversion of the first primary radiation into a first conversion radiation in such a way that the first phosphor forms a first emitting surface of the light emitting diode for the emission of a first illumination radiation, which originates from the first primary radiation and is at least partly formed by the first conversion radiation,
and the light emitting diode also having a second emitting surface for the emission of a second illumination radiation, which has a different spectral profile than the first illumination radiation, the second illumination radiation originating from the second primary radiation,
and the emitting surfaces being shaped and arranged in a plan view, looking at the light emitting diode counter to a main emitting direction thereof, in such a way that an outer of the emitting surfaces as a continuous surface area encloses an inner of the emitting surfaces at least partially,
wherein the plurality of light emitting diodes is mounted together on the common substrate.

18. The motor vehicle of claim 17,
configured to provide exterior motor vehicle illumination.

19. The motor vehicle of claim 17, further comprising:
a controller configured to control the light emitting diode module in dependence on a state of the vehicle.
